(19) United States
(12) Patent Application Publication
(10) Pub. No.: US 2025/0203937 A1
(43) Pub. Date: Jun. 19, 2025

(54) NANOSHEET DEVICES WITH REDUCED WIDTH INNER SPACER AND METHOD

(71) Applicant: GlobalFoundries U.S. Inc., Malta, NY (US)

(72) Inventors: Maria Toledano Luque, Malta, NY (US); David Charles Pritchard, Schenectady, NY (US)

(21) Appl. No.: 18/544,194

(22) Filed: Dec. 18, 2023

(51) Int. Cl. H01L 29/423; H01L 21/8234; H01L 27/088; H01L 29/06; H01L 29/08; H01L 29/417; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/017; H10D 64/018; H10D 64/258; H10D 84/0128; H10D 84/013; H10D 84/0147; H10D 84/038; H10D 84/83

(57) ABSTRACT

A structure and method include a transistor with semiconductor nanosheets, which extend between source/drain regions and which include at least a lowermost semiconductor nanosheet and an uppermost semiconductor nanosheet above the lowermost semiconductor nanosheet. The transistor includes inner gate sections below the center portions of each semiconductor nanosheet and an outer gate section with a horizontal portion above the center portion of the uppermost semiconductor nanosheet and with vertical portions on opposing sides of the semiconductor nanosheets and inner gate sections. Inner spacers are below the end portions of each semiconductor nanosheet. Outer spacers are adjacent the sidewalls of the outer gate section (including above end portions of the uppermost semiconductor nanosheet), are wider than the inner spacers, and extend onto proximal portions of the source/drain regions. Additional outer spacers are adjacent to the outer spacers (e.g., on the proximal portions or on taller and wider distal portions).

### BACKGROUND

The present disclosure relates to nanosheet devices (e.g., gate-all-around field effect transistors (GAAFETs)) and methods of forming semiconductor structures including nanosheet devices.

Gate-all-around field effect transistors (GAAFETs) have been developed to improve device drive current and electrostatics and to allow for device size scaling. However, in some cases, GAAFETs may exhibit poor drain-to-source current (Ids) because of high parasitic capacitances (e.g., overlap capacitance (Cov)/gate capacitance (Cgate)) and/or relatively long channel lengths.

### SUMMARY

Disclosed herein are embodiments of a semiconductor structure. The semiconductor structure can include a substrate and a transistor on the substrate. The transistor can include semiconductor nanosheets, which extend laterally between source/drain regions and which are stacked vertically, parallel to each other, and physically separated from each other. There can be at least two semiconductor nanosheets and, particularly, at least a lowermost semiconductor nanosheet and an uppermost semiconductor nanosheet above the lowermost semiconductor nanosheet. The transistor can further include inner spacers and outer spacers. The inner spacers can be below the end portions of all of the semiconductor nanosheets. The outer spacers can be above the end portions of the uppermost semiconductor nanosheet and can further extend onto the source/drain regions. The outer spacers can specifically be wider than the inner spacers.

In some disclosed embodiments, the semiconductor structure can include a substrate and multiple transistors on the substrate. Each of the transistors can include semiconductor nanosheets, which extend laterally between source/drain regions and which are stacked vertically, parallel to each other, and physically separated from each other. There can be at least two semiconductor nanosheets and, particularly, at least a lowermost semiconductor nanosheet and an uppermost semiconductor nanosheet above the lowermost semiconductor nanosheet. Each transistor can further include gate. The gate can have inner gate sections below center portions of the semiconductor nanosheets and an outer gate section above a center portion of the uppermost semiconductor nanosheet. Each transistor can further include inner spacers and outer spacers. The inner spacers can be below the end portions of all of the semiconductor nanosheets between the inner gate sections and proximal portions of the source/drain regions. The outer spacers can be positioned laterally adjacent to the outer gate section and can further extend over the end portions of the uppermost semiconductor nanosheet onto the proximal portions of the source/drain regions. The outer spacers can specifically be wider than the inner spacers.

Also disclosed herein are method embodiments for forming such semiconductor structures. For example, a method can include providing a substrate and forming a transistor on the substrate. The transistor can be formed so that it includes semiconductor nanosheets, which extend laterally between source/drain regions, and which are stacked vertically, parallel to each other, and physically separated from each other. The transistor can be formed so as to include at least two semiconductor nanosheets including at least a lowermost semiconductor nanosheet and an uppermost semiconductor nanosheet above the lowermost semiconductor nanosheet. The transistor can further be formed so as to include both inner spacers and outer spacers. The inner spacers can be formed below the end portions of all of the semiconductor nanosheets. The outer spacers can be formed above the end portions of the uppermost semiconductor nanosheet such that they extend onto the source/drain regions and such that they are wider than the inner spacers.

It should be noted that all aspects, examples, and features of disclosed embodiments mentioned in the summary above can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIGS. 1A-1K are different cross-section diagrams illustrating a disclosed embodiment of a semiconductor structure;

FIG. 2 is a flow diagram illustrating an embodiment of a method of forming the semiconductor structure of FIGS. 1A-1K;

FIGS. 3A-3C are cross-section diagrams illustrating a partially completed semiconductor structure formed according to the flow diagram of FIG. 2;

FIGS. 4A-4C are cross-section diagrams illustrating a partially completed semiconductor structure formed according to the flow diagram of FIG. 2; and

FIGS. 5-20 are cross-section diagram illustrating partially completed semiconductor structures, respectively, formed according to the flow diagram of FIG. 2.

### DETAILED DESCRIPTION

As mentioned above, gate-all-around field effect transistors (GAAFETs) have been developed to improve device drive current and electrostatics and to allow for device size scaling. However, in some cases, GAAFETs may exhibit poor drain-to-source current (Ids) because of high parasitic capacitances (e.g., overlap capacitance (Cov)/gate capacitance (Cgate)) and/or relatively long channel lengths.

In view of the foregoing, disclosed herein are embodiments of a semiconductor structure including a nanosheet device and, particularly, a GAAFET with relatively short nanosheet lengths (i.e., channel lengths) and narrow inner spacers (as compared to the outer spacers) for reduced Cov/Cgate and reduced channel and extension resistances to improve performance (e.g., to provide increased drive current). Specifically, in the disclosed embodiments, the GAAFET can include source/drain regions and semiconductor nanosheets that extend laterally between the source/drain regions. The semiconductor nanosheets may be stacked vertically, oriented in parallel, and physically separated from each other. The stack of semiconductor nanosheets may include at least a lowermost semiconductor nanosheet and an uppermost semiconductor nanosheet above the lowermost semiconductor nanosheet. The GAAFET can further include a gate with inner gate sections and an outer gate section. The inner gate sections can be below the center portions of each of the semiconductor nanosheets. The outer gate section can have a horizontal portion above the center portion of the uppermost semiconductor nanosheet and vertical portions on opposing sides of the semiconductor nanosheets and inner gate sections. Inner spacers can be below the end portions of each of the semiconductor nanosheets positioned laterally between the inner gate sections and the source/drain regions. Outer spacers can be positioned laterally adjacent to the sidewalls of the outer gate section (including above the end portions of the uppermost semiconductor nanosheet) and can be wider than the inner spacers such that they extend laterally onto proximal portions of the source/drain regions. The proximal portions of the source/drain regions can be smaller in width and height than distal portions. Additional outer spacers can be positioned laterally adjacent to the outer spacers. As discussed in greater detail below, in some cases, the additional outer spacers can be located on the taller distal portions of the source/drain regions. In other cases, the additional outer spacers can be located on the shorter proximal portions of the source/drain regions between the outer spacers and the taller distal portions of the source/drain regions. Also disclosed herein are method embodiments for forming the disclosed structures.

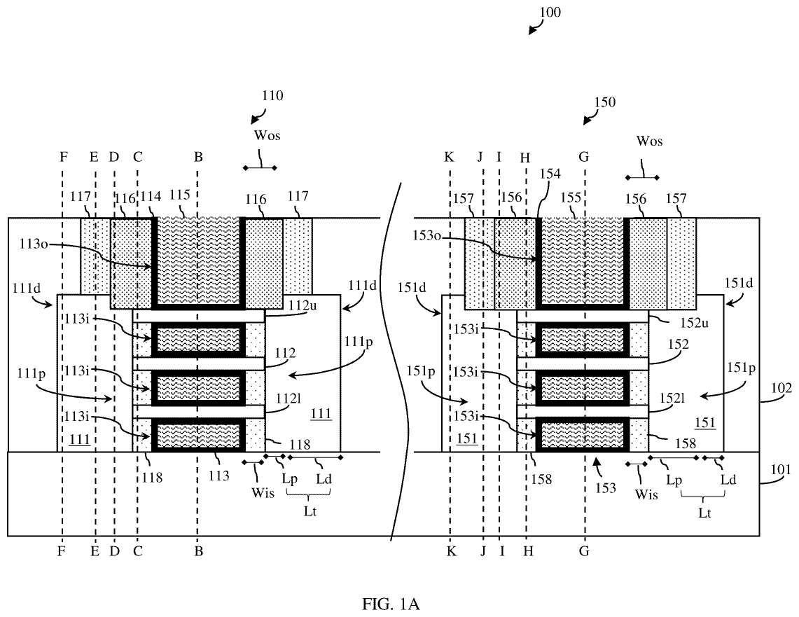

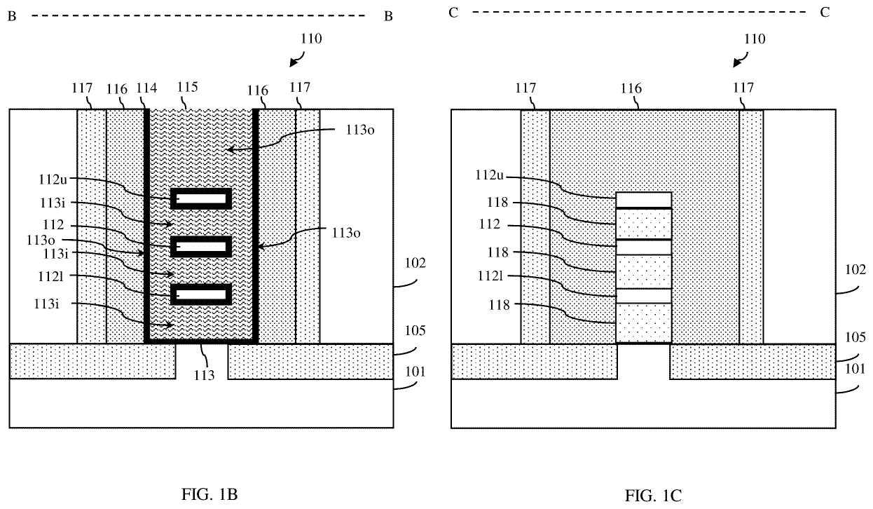

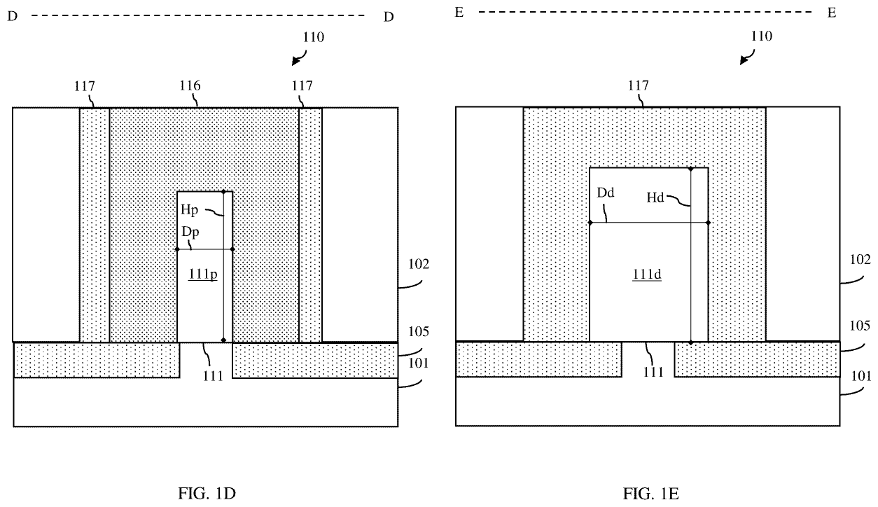

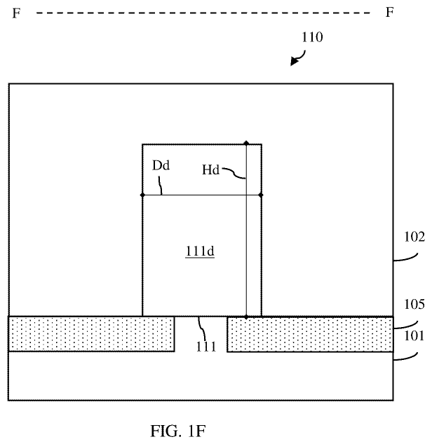

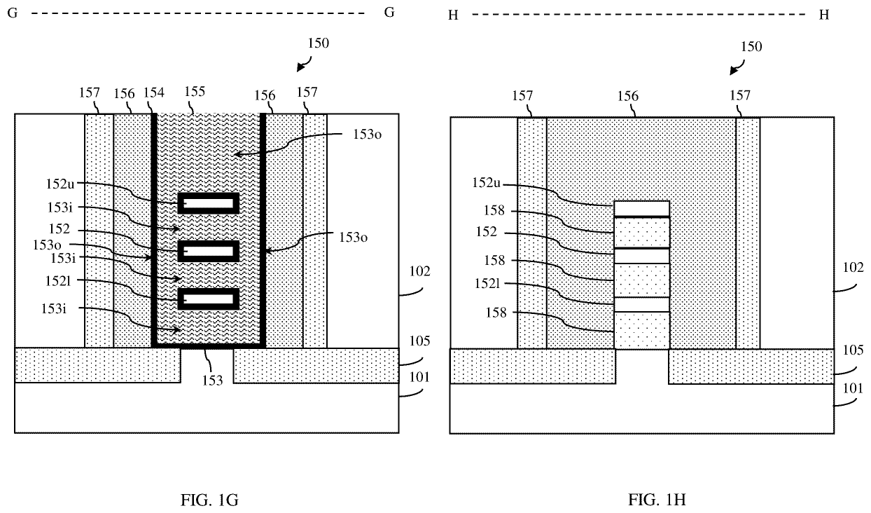

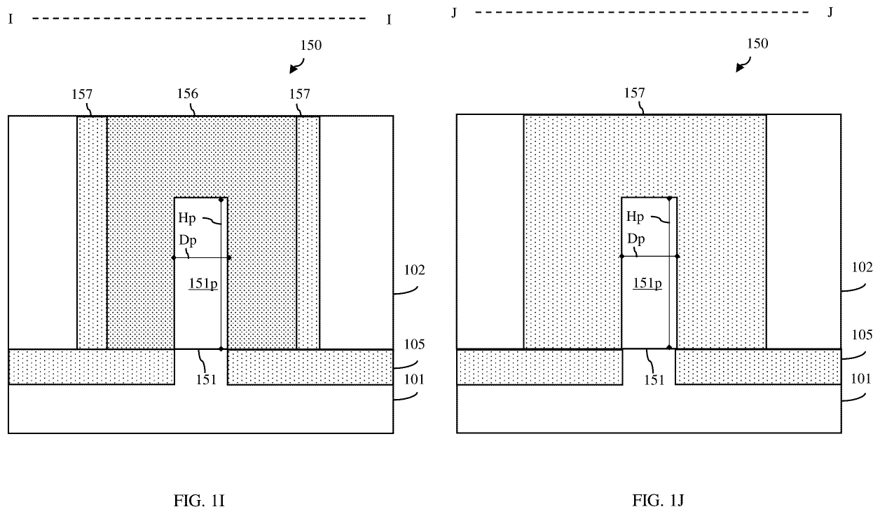

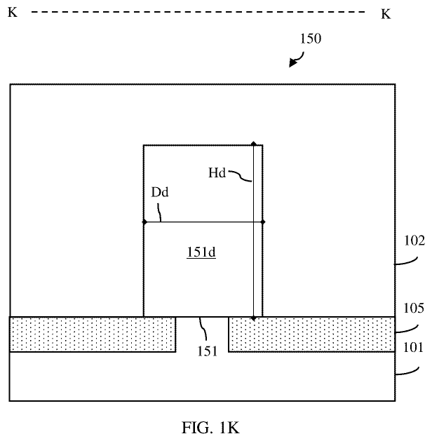

FIGS. 1A-1K are different cross-section diagrams illustrating an embodiment of a semiconductor structure 100 disclosed herein. Referring to FIGS. 1A-1K, semiconductor structure 100 can include a substrate 101 and at least one GAAFET 110, 150 on substrate 101. Semiconductor structure 100 can be a bulk semiconductor structure (as illustrated) or, alternatively, a semiconductor-on-insulator structure. That is, substrate 101 can be a bulk semiconductor substrate (e.g., a bulk monocrystalline silicon (Si) substrate), as illustrated. Alternatively, substrate 101 can be a semiconductor-on-insulator substrate (e.g., a silicon-on-insulator (SOI) substrate). Those skilled in the art will recognize that GAAFETs can be formed on either bulk or semiconductor-on-insulator substrates. However, depending on the type of substrate, initial processing techniques employed to enable nanosheet formation and provide device-to-substrate and device-to-device isolation will vary such that resulting in-substrate components will vary. In any case, such techniques are well known in the art and, thus, have been omitted from the specification in order to allow the reader to focus on the salient aspects of the disclosed embodiments.

For purposes of illustration, semiconductor structure 100 is shown as including two GAAFETs 110, 150 (also referred to herein as first GAAFET 110 and second GAAFET 150) on substrate 101. GAAFET 110 can have a first type conductivity and GAAFET 150 can have a second type conductivity that is different from the first type conductivity. Given the process flow required to form GAAFETs with different type conductivities on the same substrate 101, GAAFET 110 and GAAFET 150 will have somewhat different structural configurations, as discussed below. To illustrate the structural similarities and differences between GAAFETs 110 and 150, FIGS. 1B-1F show different cross-sections BB to FF of GAAFET 110 and FIGS. 1G-1K show different cross-sections GG to KK of GAAFET 150. For purposes of illustration, GAAFET 110 is described herein as being a P-channel GAAFET and GAAFET 150 is described herein as being an N-channel GAAFET. However, it should be understood that the description is not intended to be limiting. Alternatively, GAAFET 110 could be an N-channel GAAFET and GAAFET 150 could be a P-channel GAAFET.

Each GAAFET 110, 150 can include source/drain regions 111, 151 above substrate 101. Source/drain regions 111, 151 can include epitaxial monocrystalline semiconductor material (e.g., epitaxial monocrystalline silicon (Si) or some other suitable epitaxial monocrystalline semiconductor material) doped so as to have the appropriate conductivity type and level given the GAAFET conductivity type. For example, a P-channel GAAFET (e.g., GAAFET 110) can have source/drain regions doped so as to have P-type conductivity at a relatively high conductivity level (i.e., to be P++ source/drain regions); whereas an N-channel GAAFET (e.g., GAAFET 150) can have source/drain regions doped so as to have N-type conductivity at a relatively high conductivity level (i.e., to be N++ source/drain regions).

Each GAAFET 110, 150 can further include multiple semiconductor nanosheets 112, 152 (hereinafter referred to as nanosheets) extending laterally between the source/drain regions 111, 151. For purposes of this disclosure, a nanosheet refers to a relatively thin, elongated, semiconductor body having a thickness dimension (as measured in a first direction, which is perpendicular to the top surface of the substrate) of, for example, 20 nm or less (e.g., 3-20 nm). For example, in some embodiments, the nanosheets can have a thickness of 3-10 nm (e.g., 10 nm, 7 nm, 6.5 nm, 5 nm, 3 nm, etc.). The length of a nanosheet (as measured in a second direction, which is parallel to the surface of the substrate) from one source/drain region to the other can be 100 nm or less (e.g., between 10 and 50 nm). A width of the nanosheet (as measured in a third direction, which is parallel to the surface of the substrate and oriented perpendicular to the second direction) can be, for example, 20 nm or less. When the thickness of a nanosheet is approximately equal to its width, the nanosheet can be referred to as a nanowire. Nanosheets 112, 152 can be stacked vertically (i.e., one above the other), parallel, and physically separated. Nanosheets 112, 152 can include at least a lowermost semiconductor nanosheet 1121, 1521 proximal to, but physically separated from, substrate 101, and an uppermost semiconductor nanosheet 112u, 152u above the lowermost semiconductor nanosheet 1121, 1521. Optionally, one or more additional nanosheets can be stacked between lowermost semiconductor nanosheet 1121, 1521 and uppermost semiconductor nanosheet 112u, 152u. The spacing between the lowermost semiconductor nanosheet 1121, 1521 and the substrate 101 and further between adjacent semiconductor nanosheets within the stack can be, for example, between 5-20 nm (e.g., approximately 15 nm). For purposes of illustration, three nanosheets are shown in GAAFET 110 and in GAAFET 150. However, it should be understood that the figures are not intended to be limiting. Such GAAFETs can include any number of two or more stacked nanosheets. Furthermore, the number of nanosheets 112 in GAAFET 110 can be the same as or different from the number of nanosheets 152 in GAAFET 150. In any case, nanosheets 112, 152 can be made of a monocrystalline semiconductor material (e.g., monocrystalline silicon (Si)) or some other suitable monocrystalline semiconductor material.

Nanosheets 112, 152 can each include end portions, which are immediately adjacent to proximal portions 111p, 151p of source/drain regions 111, 151, respectively, and a center portion, which is positioned laterally between the end portions. The center portions of nanosheets 112, 152 can be the channel regions and the end portions can be the source/drain extension regions of GAAFETs 110, 150. Thus, in a P-channel GAAFET (e.g., GAAFET 110), the center portions of the nanosheets can be doped so as to have N-type conductivity at a relatively low conductivity level (i.e., to be N-channel regions) or, alternatively, can be undoped (i.e., to be intrinsic channel regions). Additionally, in a P-channel GAAFET, the end portions of the nanosheets can be doped so as to have P-type conductivity at a relatively low conductivity level (e.g., so as to be P-source/drain extensions). In an N-channel GAAFET (e.g., GAAFET 150), the center portions of the nanosheets can be doped so as to have P-type conductivity at a relatively low conductivity level (i.e., to be P-channel regions) or, alternatively, undoped (i.e., to be intrinsic channel regions). Additionally, in an N-channel GAAFET, the end portions of nanosheets can be doped so as to have N-type conductivity at a relatively low conductivity level (i.e., to be N-source/drain extension regions).

GAAFETs 110, 150 can each further include a gate 113, 153. Gate 113, 153 can wrap entirely around the center portions (i.e., the channel regions) of each of the nanosheets 112, 152. That is, gate 113, 153 can be adjacent to the bottom, top, and opposing side surfaces of the center portion (i.e., channel region) of each nanosheet. Gate 113, 153 can be, for example, a replacement metal gate (RMG). Gate 113, 153 can include a gate dielectric layer 114, 154 including a stack of one or more conformal layers of gate dielectric material (e.g., a thin oxide layer and/or a high-K dielectric layer) immediately adjacent to the bottom, top, and opposing side surfaces of the center portions of nanosheets 112, 152. Gate 113, 153 can further include a gate conductor layer 115, 155 including one or more layers of gate conductor material (e.g., one or more conformal metal layers, a fill metal layer, etc.) on gate dielectric layer 114. Gates 113, 153 of GAAFETs 110, 150 can be essentially the same (e.g., same gate dielectric and conductor materials). Alternatively, gates 113 and 153 could be different. That is, gate dielectric and/or gate conductor materials in the gates 113 and 153 can vary. For example, gates 113, 153 could include different work function metals. In any case, to avoid clutter in the drawings and to allow the reader to focus on the salient aspects of the disclosed structures, the specific gate dielectric layer(s) and gate conductor layer(s) within the gate 113, 153 are described herein or illustrated.

Gates 113, 153 includes inner gate sections 113i, 153i and an outer gate section 1130, 1530. Inner gate sections 113i, 153i can be aligned below the center portions of nanosheets 112, 152 (e.g., between substrate 101 and lowermost semiconductor nanosheet 1121, 1521 and further between each pair of adjacent nanosheets). Outer gate section 1130, 1530 can include a horizontal portion above and immediately adjacent to the center portion of uppermost semiconductor nanosheet 112u, 152u. Outer gate section 1130, 1530 can further include vertical portions positioned laterally adjacent to opposing sides of nanosheets 112, 152 and opposing sides of inner gate sections 113i, 153i therebetween and can extend from substrate 101 up to the horizontal portion. A gate length of the inner gate sections 113i, 153i (e.g., as measured in a direction parallel to the channel lengths) can be essentially the same (e.g., plus or minus 10%) as a gate length of the outer gate section 1130, 1530.

To provide electrical isolation between gate 113, 153 and source/drain regions 111, 151 and to minimize parasitic gate-to-source/drain capacitance, GAAFET 110, 150 can further include various dielectric spacers. The dielectric spacers can include inner spacers 118, 158 as well as outer spacers 116, 156 and additional outer spacers 117, 157. Inner spacers 118, 158 can be aligned below end portions of nanosheets 112, 152 so as to be positioned laterally between sidewalls of inner gate sections 113i, 153i and adjacent source/drain regions 111, 151. Outer spacers 116, 156 can be positioned laterally immediately adjacent to outer sidewalls of outer gate sections 1130, 1530. Thus, outer spacers 116, 156 can have portions above the end portions of uppermost semiconductor nanosheet 112u, 152u on opposing sides of the outer gate section 1130, 1530 (e.g., as illustrated in FIG. 1A) as well as portions on all other sidewalls of the outer gate section 1130, 1530 (e.g., as illustrated in FIGS. 1B-1D for GAAFET 110 and in FIGS. 1G-1I for GAAFET 150). In the disclosed embodiments, outer spacers 116, 156 can be wider than inner spacers 118, 158. That is, a width (Wos) of outer spacers 116, 156 can be greater than a width (Wis) of inner spacers 118, 158. For example, Wis can be less than ⅞*Wos (e.g., ¾*Wos, ½*Wos, or ⅓*Wos). Furthermore, outer spacers 116, 156 can extend laterally beyond the end portions (i.e., beyond the end walls) of the nanosheets 112, 152 onto the top surface and opposing sides of proximal portions 111p, 151p of source/drain regions 111, 151. As discussed below with regard to the method, outer spacers 116 and 156 of GAAFETs 110 and 150 are formed concurrently, whereas inner spacers 118 and 158 are formed in separate process steps. Therefore, Wos of outer spacers 116 of GAAFET 110 will be essentially the same as Wos of outer spacers 156 of GAAFET 150; however, Wis of inner spacers 118 of GAAFET 110 can be the same as or different from Wis of inner spacers 158 of GAAFET 150.

It should be noted that proximal portions 111p, 151p of source/drain regions 111, 151 (which, as mentioned above, have outer spacers 116, 156 thereon) can be positioned laterally between distal portion 111d, 151d and the end portions of nanosheets 112, 152 (which, as mentioned above, have inner spacers 118, 158 below). The overall length (Lt) of each source/drain region 111, 151 is the sum of the lengths of the proximal and distal portions (Lp and Ld). The cross-sectional areas of proximal portions 111p, 151p can be less than the cross-sectional area of distal portions 111d, 151d. That is, as illustrated in FIGS. 1D-1F for GAAFET 110 and as illustrated in FIGS. 1I-1K for GAAFET 150 and measured from a top surface of substrate 101, heights (Hd) of distal portions 111d, 151d of source/drain regions 111, 151 can be greater than heights (Hp) of proximal portions 111p, 151p of source/drain regions 111, 151. Additionally, as illustrated in FIGS. 1D-1F for GAAFET 110 and as illustrated in FIGS. 1I-1K for GAAFET 150 and measured in the direction parallel to the channel widths, depths (Dd) of distal portions 111d, 151d of source/drain regions 111, 151 can be greater than depths (dp) of proximal portions 111p, 151p of source/drain regions 111, 151.

As mentioned above, the dielectric spacers can also include additional outer spacers 117, 157. However, given the process flow required to form GAAFETs with different type conductivities on the same substrate 101, the additional outer spacers 117 in GAAFET 110 will be somewhat different from the additional outer spacers 157 in GAAFET 150. Specifically, as illustrated in FIG. 1A and FIGS. 1B-1F, in GAAFET 110, additional outer spacers 117 can be positioned laterally immediately adjacent to outer spacers 116, but on distal portions 111d of source/drain regions 111 (as opposed to on the proximal portions 111p). Furthermore, since distal portions 111d of source/drain regions 111 have a different cross-sectional area than proximal portions 111p, the bottom surfaces of outer spacers 116 and additional outer spacers 117 are not aligned (i.e., are non-coplanar). For example, above source/drain region 111, bottom surfaces of additional outer spacers 117 will be at a higher level above the substrate 101 than bottom surfaces of outer spacers 116. In GAAFET 110, the length of the proximal portion (Lp) is defined by the amount of outer spacer material that extends beyond the end wall of uppermost semiconductor nanosheet 112u. As illustrated in FIG. 1A and FIGS. 1G-1K, in GAAFET 150, additional outer spacers 157 can be positioned laterally immediately adjacent to outer spacers 156 above proximal portions 151p of source/drain regions 151 (as opposed to above the distal portions). Thus, the bottom surfaces of outer spacers 156 and additional outer spacers 157 are coplanar. For example, above source/drain region 151, bottom surfaces of additional outer spacers 157 will be at the same level above the substrate 101 than bottom surfaces of outer spacers 156. In GAAFET 150, the length of the proximal portion (Lp) is defined by the amount of outer spacer material that extends beyond the end wall of uppermost semiconductor nanosheet 152u plus the width of the additional outer spacer 157. Consequently, Lp in GAAFET 110 will be less than Lp in GAAFET 150.

It should be noted that, in each GAAFET 110, 150, inner spacers 118, 158, outer spacers 116, 156, and additional outer spacers 117, 157 can be made of dielectric materials sufficient to provide isolation between gate 113, 153 and source/drain regions 111, 151. The dielectric materials can be, for example, low-K dielectric materials. For purposes of this disclosure, a low-K dielectric material refers to a dielectric material having a dielectric constant (K) that is less than the dielectric constant of silicon dioxide (i.e., K<3.9). Thus, for example, dielectric spacer materials can be silicon boron carbonitride (SiBCN), silicon oxycarbonitride (SiOCN), silicon carbonitride (SiCN) or any other suitable low-K dielectric material. Furthermore, at least the outer spacer dielectric material can be sufficiently different from both the inner spacer dielectric material and the additional outer spacer dielectric material to enable the inner spacer dielectric material and the additional outer spacer dielectric material to be selectively etched over the outer spacer dielectric material during processing.

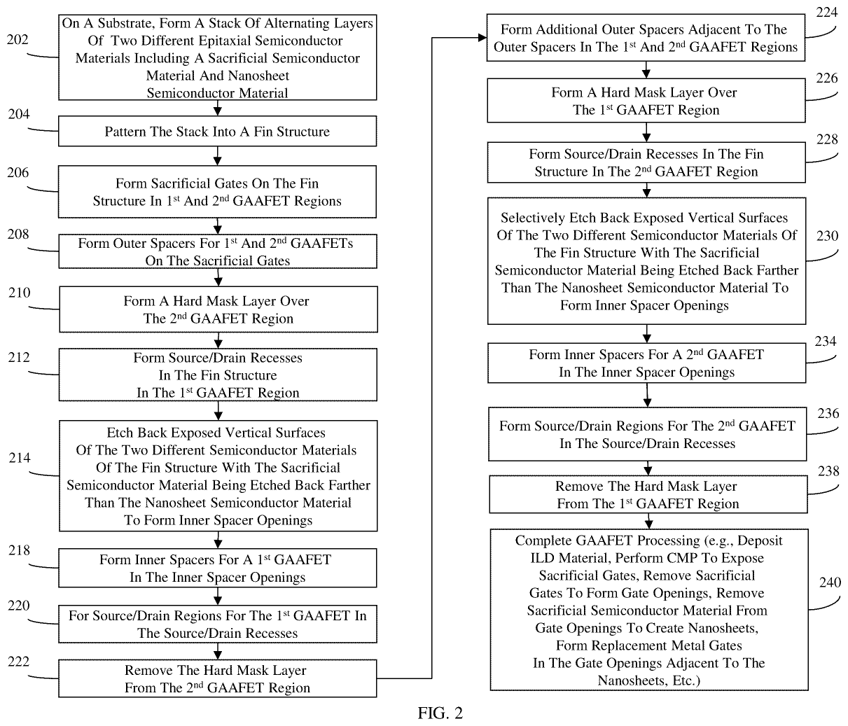

FIG. 2 is a flow diagram illustrating embodiments of a method for forming the semiconductor structure 100 of FIGS. 1A-1K. The method can include providing a substrate 101. The substrate 101 can, for example, be a bulk monocrystalline semiconductor substrate such as a bulk monocrystalline silicon substrate, as illustrated. Alternatively, the substrate 101 could be a semiconductor-on-insulator substrate (e.g., a silicon-on-insulator (SOI) substrate).

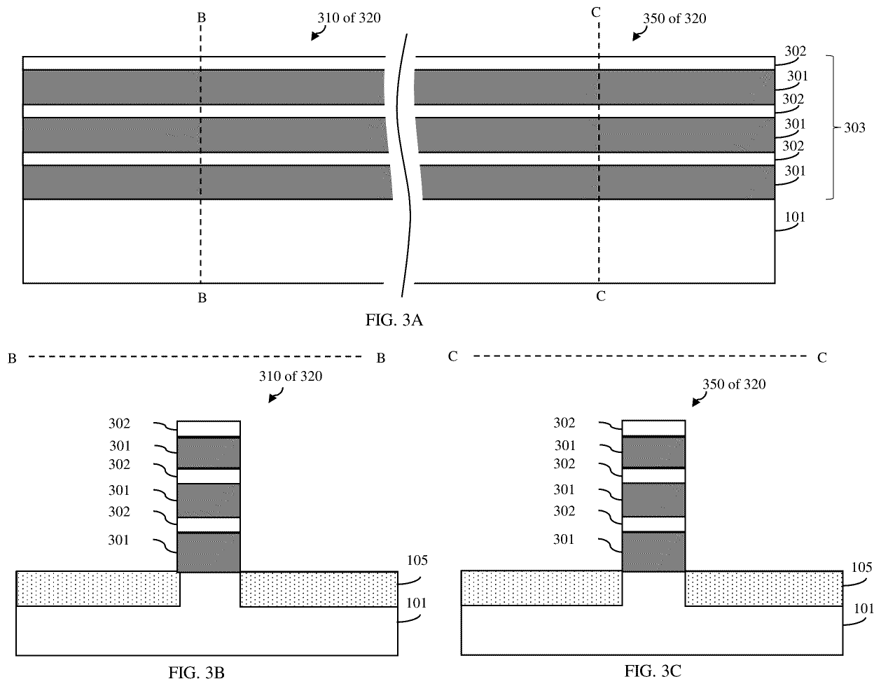

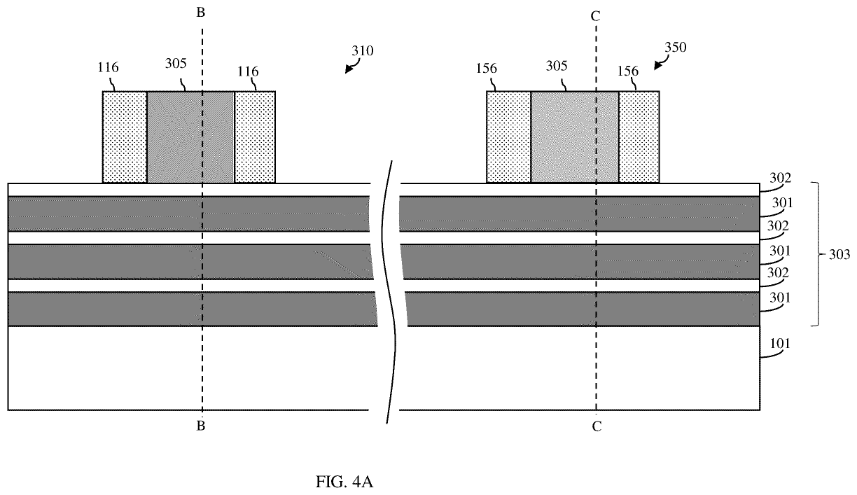

The method can include forming a stack 303 of alternating layers of two different epitaxial semiconductor materials 301 and 302 on substrate 101 (see process 202 and FIG. 3A). The two different epitaxial semiconductor materials can include a sacrificial semiconductor material (which will be completely removed from the structure during processing) and a nanosheet semiconductor material (which will ultimately be used to form semiconductor nanosheets during processing). Sacrificial semiconductor material 301 can be, for example, monocrystalline silicon germanium (e.g., with 20% germanium or more) or monocrystalline germanium. Nanosheet semiconductor material 302 can be, for example, monocrystalline silicon such that stack 303 is also referred to herein as a silicon/silicon germanium superlattice. In some embodiments, within stack 303, nanosheet semiconductor material 302 can be in relatively thin layers as compared to sacrificial semiconductor material 301. For example, in some embodiments, the layers of nanosheet semiconductor material 302 can have a thickness of 3-10 nm (e.g., approximately 7 nm, 6.5 nm, 5 nm, etc.) and the layers of sacrificial semiconductor material 301 can have a thickness of 5-20 nm (e.g., approximately 15 nm). As illustrated, within stack 303, the lowermost layer can be a layer of sacrificial semiconductor material 301 and the uppermost layer can be a layer of nanosheet semiconductor material 302. Furthermore, stack 303 can include at least two layers of nanosheet semiconductor material 302.

The method can further include patterning stack 303 into at least one multi-layered fin structure 320 (see process 204 and FIGS. 3A-3C). For example, using conventional lithographic patterning and etch techniques, trench(es) can be formed extending through stack 303 and partially into the substrate 101 to define multi-layered fin structure(s) 320. For purposes of this disclosure, a fin structure refers to an elongated three-dimensional rectangular-shaped body. Isolation material (e.g., silicon dioxide or some other suitable isolation material) can be deposited to fill the trench and subsequently recessed to expose fin structure 320 above the level of substrate 101. Recessing of the isolation material can be stopped prior to exposure of substrate 101 such that trench isolation region(s) 105 remain in substrate 101 laterally surrounding the lower portion of fin structure(s) 320. Portions of the same fin structure or, alternatively, discrete fin structures can be formed in a first GAAFET region 310 within which a first GAAFET will be formed and in a second GAAFET region 350, within which a second GAAFET will be formed. For purposes of illustration, the first GAAFET is described herein as being formed as a P-channel GAAFET and the second GAAFET is described herein as being formed as an N-channel GAAFET. However, it should be understood that, alternatively, the first GAAFET could be formed as an N-channel GAAFET and the second GAAFET could be formed as a P-channel GAAFET.

It should be noted that nanosheet semiconductor material 302 in first and second regions 310, 350 can be intrinsic (i.e., left undoped). Alternatively, nanosheet semiconductor material 302 in first and second GAAFET regions 310, 350 can be doped so as to have different type conductivities, respectively, at relatively low conductivity levels. For example, for a P-channel GAAFET in first GAAFET region 310, nanosheet semiconductor material 302 could be doped so as to have N-type conductivity at a relatively low conductivity level (e.g., for formation of N-channel regions). For a for an N-channel GAAFET in second GAAFET region 350, nanosheet semiconductor material 302 could be doped so as to have P-type conductivity at a relatively low conductivity level (e.g., for formation of P-channel regions).

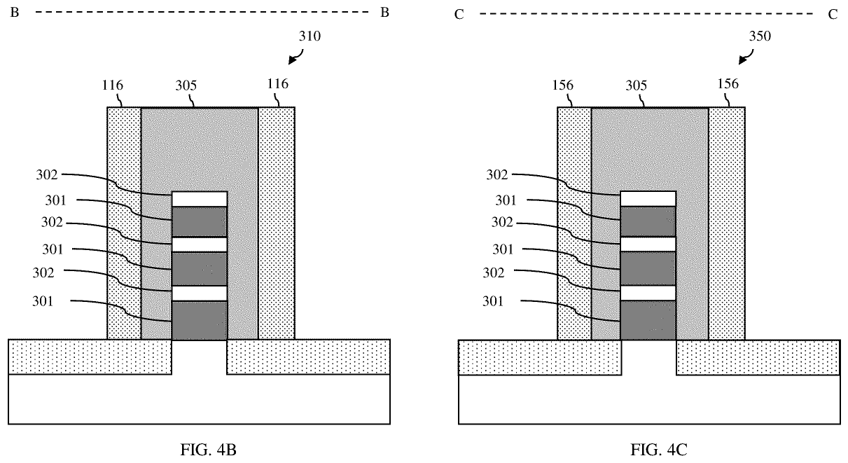

The method can further include forming sacrificial gates 305 for first and second GAAFETs on fin structure(s) 320 in first and second GAAFET regions 310, 350, respectively (see process 206 and FIGS. 4A-4C). Formation of sacrificial gates 305 can include, for example, formation of an optional conformal silicon dioxide layer (not shown) over fin structure 320 and formation of a blanket sacrificial layer on the conformal silicon dioxide layer. The blanket sacrificial layer can be a layer of a suitable sacrificial gate material (e.g., polysilicon, amorphous silicon, etc.), which is different in crystalline structure and/or material elements from substrate 101, sacrificial semiconductor material 301, and nanosheet semiconductor material 302 so that it can be selectively etch away from these materials during subsequent processing. A sacrificial dielectric cap layer (e.g., a silicon nitride cap layer) can be deposited onto the blanket sacrificial layer. The resulting sacrificial gate stack can be lithographically patterned and etched to form sacrificial gates 305.

The method can further include forming outer spacers 116, 156 on sacrificial gates 305 in first and second GAAFET regions 310, 350 (see process 208 and FIGS. 4A-4C). Outer spacer formation can be accomplished using conventional gate sidewall spacer formation techniques. For example, a conformal layer of dielectric spacer material can be deposited over the partially completed structure. The dielectric spacer material for outer spacers 116, 156 can be, for example, a low-K dielectric material, such as SiBCN, SiOCN, SiCN or any other suitable low-K dielectric material. A selective anisotropic etch process can subsequently be performed to remove exposed horizontal portions of the dielectric spacer material, leaving intact the vertical portions as outer spacers 116, 156.

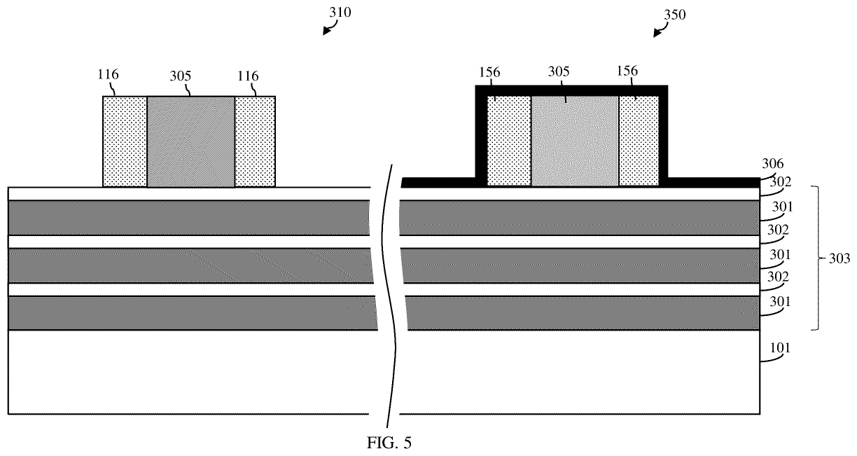

The method can further include forming a hard mask layer 306 over second GAAFET region 350 (see process 210 and FIG. 5). For example, a conformal layer of silicon nitride or some other suitable hard mask material can be deposited over the partially completed structure. Hard mask layer 306 can subsequently be lithographically patterned and etched to expose first GAAFET region 310.

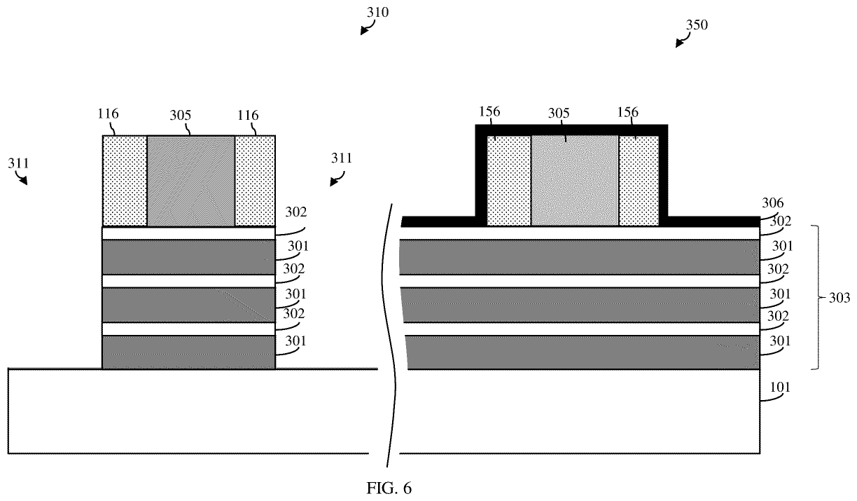

The method can further include forming source/drain recesses 311 in exposed portions of fin structure 320 within first GAAFET region 310 (see process 212 and FIG. 6). Specifically, selective anisotropic etch process(es) can be performed to remove portions of fin structure 320 that extend laterally beyond outer spacers 116 on either side of sacrificial gate 305 within first GAAFET region 310.

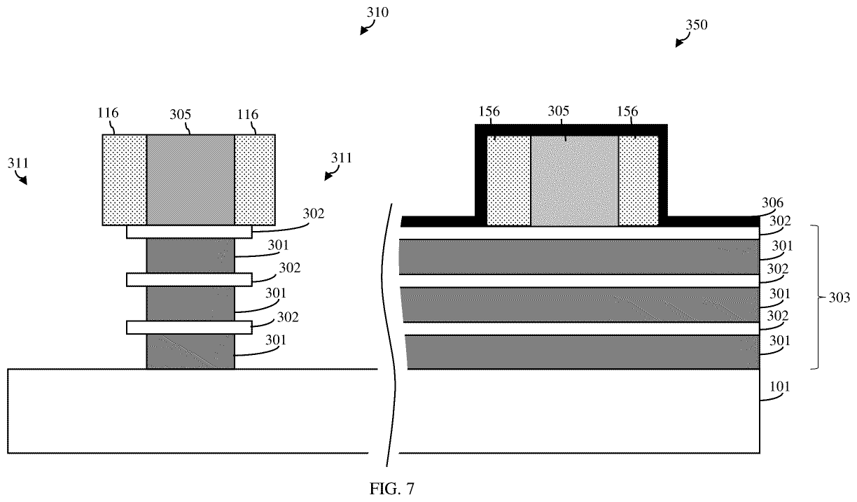

The method can further include etching back and, particularly, laterally etching the vertical surfaces of semiconductor materials 301 and 302 exposed within source/drain recesses 311 in a manner that results in the sacrificial semiconductor material 301 being etched back farther than the nanosheet semiconductor material 302 to form inner spacer openings (see process 214 and FIG. 7). For example, a selective isotropic etch process could be performed to etch back exposed vertical surfaces of nanosheet semiconductor material 302 (over the sacrificial semiconductor material 301) by a first distance (e.g., approximately ½ the width of the outer spacers 116 or by some other distance less than the full width of the outer spacers 116). This selective isotropic etch of the nanosheet semiconductor material 302 could be performed before or after a separate selective isotropic etch process performed to etch back exposed vertical surfaces of sacrificial semiconductor material 301 by a second distance greater than the first distance. For example, consider the example where nanosheet semiconductor material 302 is silicon and sacrificial semiconductor material 301 is silicon germanium. Silicon could be selectively and isotropically etched over silicon germanium in CF₄/O₂/N₂ and NF₃/O₂/N₂ based plasmas. Alternatively, any other suitable isotropic etch process selective for silicon over silicon germanium could be used. In a separate process, silicon germanium could be etched selectively and isotropically over silicon using a chlorine trifluoride (CIF₃) vapor phase etch process or a wet etch process that employs a standard clean solution no. 1 (SC1) at an elevated temperature (e.g., approximately 40° C.) could be employed to etch silicon germanium over silicon. Alternatively, any other suitable isotropic etch process selective to silicon germanium over silicon could be performed.

It should be noted that the etch processes described above are for illustration purposes. Alternatively, any other suitable isotropic etch process(es) could be employed at process 214 to achieve the partially completed structure illustrated in FIG. 7. For example, a non-selective isotropic etch process could be performed to concurrently etch back both semiconductor materials essentially the same first distance, followed by a selective isotropic etch process to further etch the sacrificial semiconductor material. Alternatively, a single isotropic etch process could be performed that etches the sacrificial semiconductor material at a slightly faster rate than the nanosheet semiconductor material.

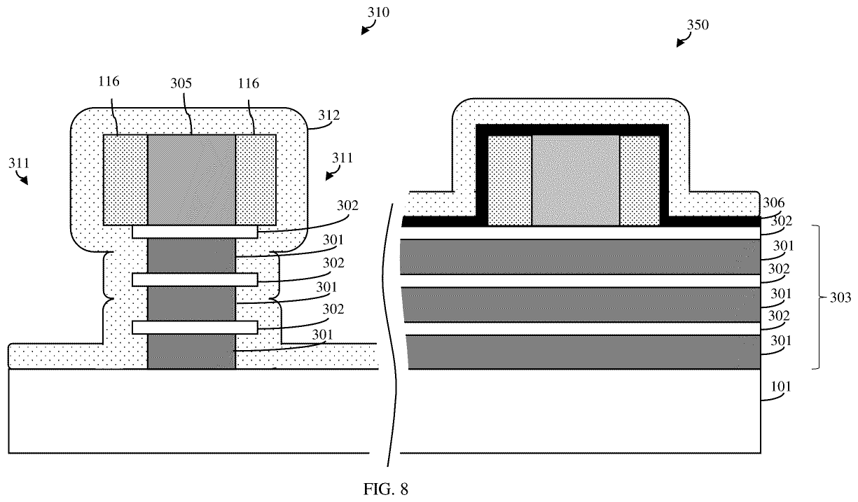

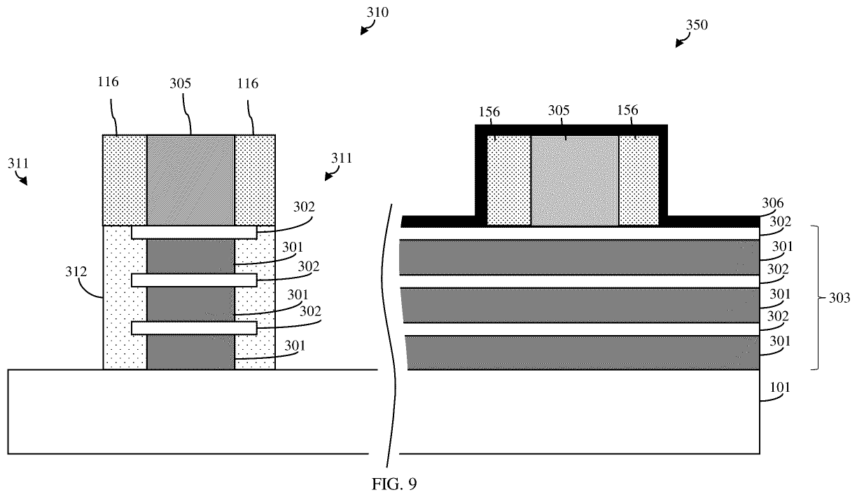

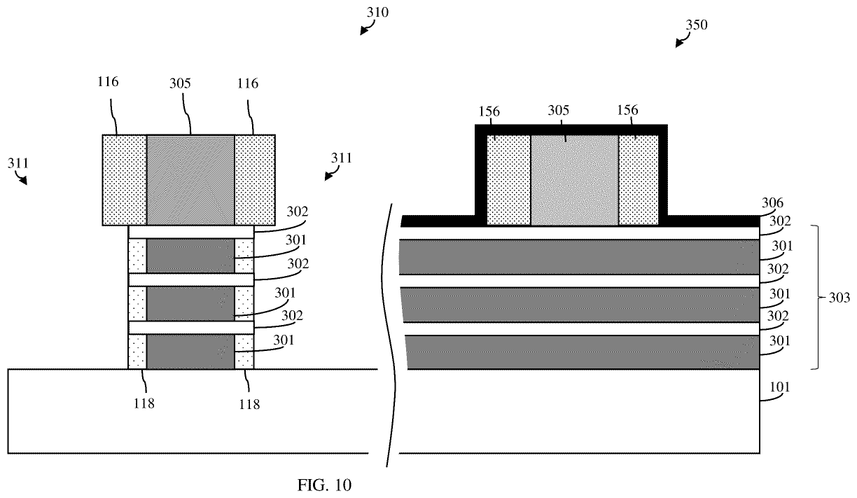

Inner spacers 118 can then be formed within the inner spacer openings (see process 218). For example, a conformal layer of dielectric spacer material 312 can be deposited over the partially completed structure (see FIG. 8). The dielectric spacer material 312 can be, for example, a low-K dielectric material, such as SiBCN, SiOCN, SiCN or any other suitable low-K dielectric material, that is different from the low-K dielectric material previously used for outer spacers 116, 156. A selective anisotropic etch process can then be performed to remove all dielectric spacer material 312 not protected by outer spacers 116 (see FIG. 9). Then, a selective isotropic etch process can be performed to etch back and, particularly, to laterally etch dielectric spacer material 312 below outer spacers 116 to expose the vertical surfaces of nanosheet semiconductor material 302 (see FIG. 10). This selective isotropic etch process can specifically be stopped before dielectric spacer material 312 is completely removed from the inner spacer openings. Thus, inner spacers 118 remain within the inner spacer openings covering the vertical surfaces of the sacrificial semiconductor material 301. Techniques for selectively anisotropically etching and selectively isotropically etching various dielectric materials are well known in the art and will vary depending upon the specific dielectric material being etched.

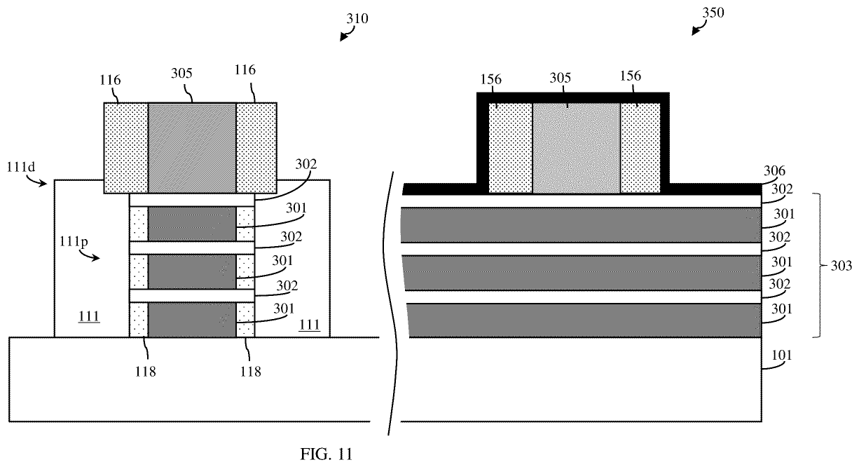

Source/drain regions 111 can subsequently be formed in source/drain recesses 311 (see process 220 and FIG. 11). Source/drain regions 111 can be formed, for example, by epitaxially growing a monocrystalline semiconductor material on the exposed vertical surfaces (i.e., end walls) of nanosheet semiconductor material 302 within source/drain recesses 311. This semiconductor material can be, for example, monocrystalline silicon or some other suitable monocrystalline semiconductor material, which is preselected, for example, to improve channel mobility depending upon the conductivity type of GAAFET being formed. Additionally, source/drain regions 111 can be in situ doped, during epitaxial deposition, so as to have a suitable conductivity type and level given the conductivity type of the GAAFET being formed. For example, for a P-channel GAAFET, source/drain regions 111 can be in situ doped so as to have P-type conductivity at a relatively high conductivity level (i.e., P++ conductivity). As illustrated, the epitaxial deposition process can be performed so that source/drain regions 111 include: proximal portions 111p, which are adjacent to fin structure 320 and bound by outer spacers 116; and distal portions 111d, which extend laterally beyond outer spacers 116. Since distal portions 111d of source/drain regions 111 are not bound by outer spacers 116, distal portions 111d can have greater cross-sectional areas than proximal portions 111p (i.e., distal portions 111d can have a greater height as measured from substrate 101 and a greater depth as measured parallel to the channel width than the proximal portions 111p).

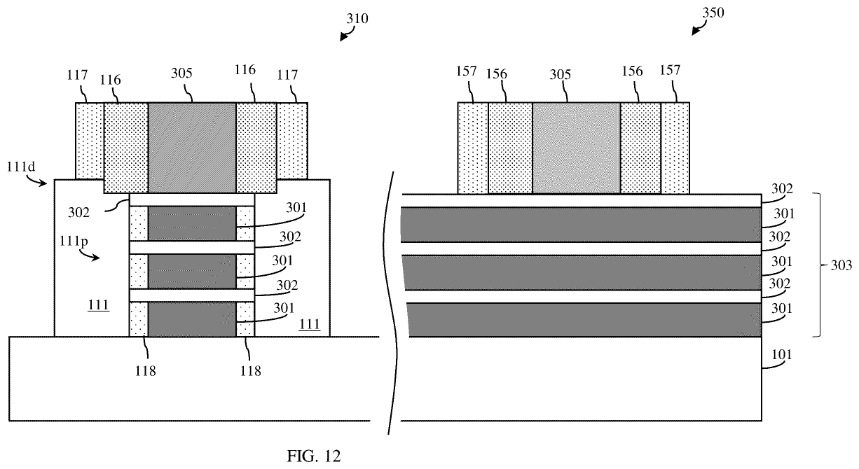

Subsequently, hard mask layer 306 over second GAAFET region 350 can be selectively removed (see process 222). Then, additional outer spacers 117, 157 can be formed in the first and second GAAFET regions 310, 350 such that they are positioned laterally adjacent to outer spacers 116, 156 (see process 224 and FIG. 12). Like outer spacer formation, additional outer spacer formation can be accomplished using conventional gate sidewall spacer formation techniques. For example, a conformal layer of dielectric spacer material can be deposited over the partially completed structure. The dielectric spacer material for additional outer spacers 117, 157 can be, for example, a low-K dielectric material, such as SiBCN, SiOCN, SiCN or any other suitable low-K dielectric material. However, the dielectric spacer material used for additional outer spacers 117, 157 should be different from the dielectric spacer material used for outer spacers 116, 156. Then, a selective anisotropic etch process can be performed to remove exposed horizontal portions of the dielectric spacer material, leaving intact vertical portions as additional outer spacers 117, 157.

It should be noted that, in first GAAFET region 310, additional outer spacers 117 for the first GAAFET are formed on distal portions 111d of the previously formed source/drain region 111 for the first GAAFET. Thus, bottom surfaces of additional outer spacers 117 and outer spacers 116 are not aligned (i.e., non-coplanar). However, in second GAAFET region 350, additional outer spacers 157 are formed on the uppermost layer of nanosheet semiconductor material 302 in stack 303 prior to formation of the source/drain regions for the second GAAFET. Thus, bottom surfaces of additional outer spacers 157 and outer spacers 156 are aligned (i.e., coplanar).

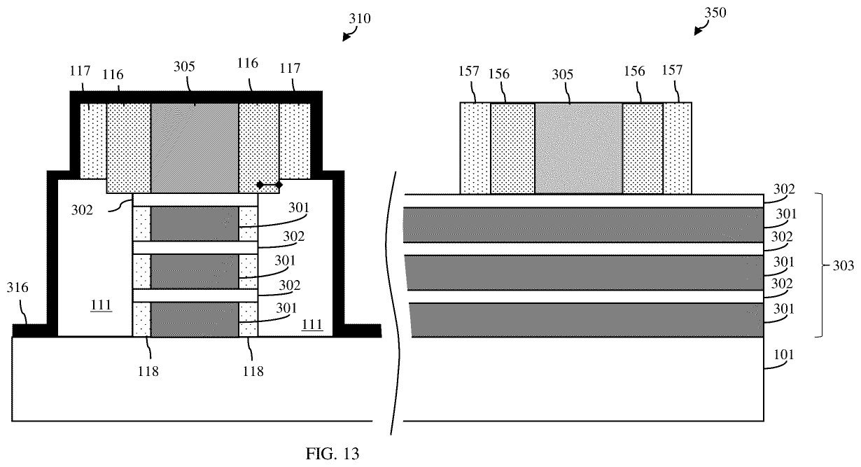

The method can further include forming a hard mask layer 316 over first GAAFET region 310 (see process 226 and FIG. 13). For example, a conformal layer of silicon nitride or some other suitable hard mask material can be deposited over the partially completed structure. Hard mask layer 316 can subsequently be lithographically patterned and etched to expose second GAAFET region 350.

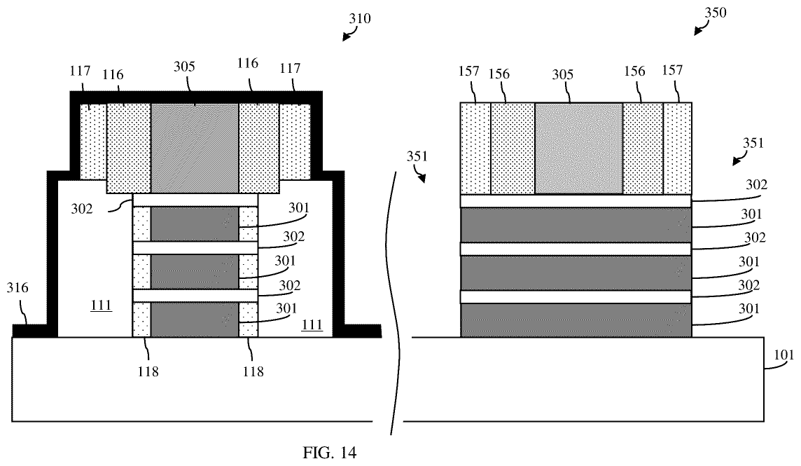

The method can further include forming source/drain recesses 351 in exposed portions of fin structure 320 within second GAAFET region 350 (see process 228 and FIG. 14). Specifically, selective anisotropic etch process(es) can be performed to remove portions of fin structure 320 that extend laterally beyond outer spacers 156 and additional outer spacers 157 on either side of sacrificial gate 305 within second GAAFET region 350.

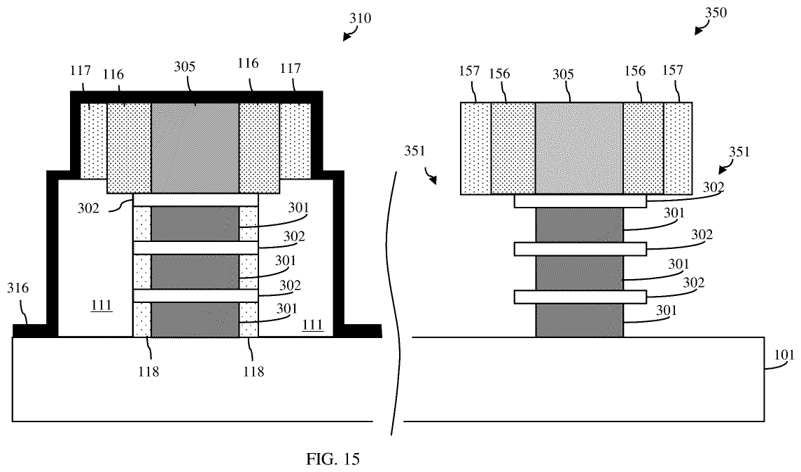

The method can further include etching back and, particularly, laterally etching the vertical surfaces of semiconductor materials 301 and 302 exposed within source/drain recesses 351 in a manner that results in the sacrificial semiconductor material 301 being etched back farther than the nanosheet semiconductor material 302 to form inner spacer openings (see process 230 and FIG. 15). Process 230 can be performed in essentially the same manner as process 214 described above.

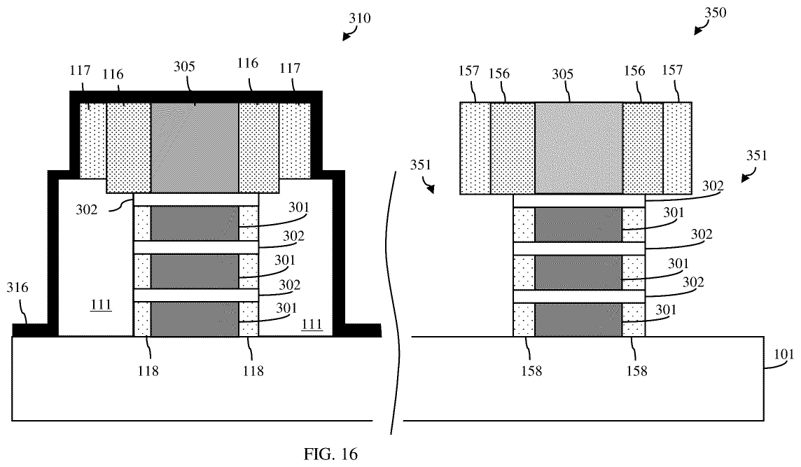

The method can further include forming inner spacers 158 within the inner spacer openings in the second GAAFET region 350 (see process 234 and FIG. 16). Process 234 can be performed essentially the same inner spacer formation technique described above at process 218.

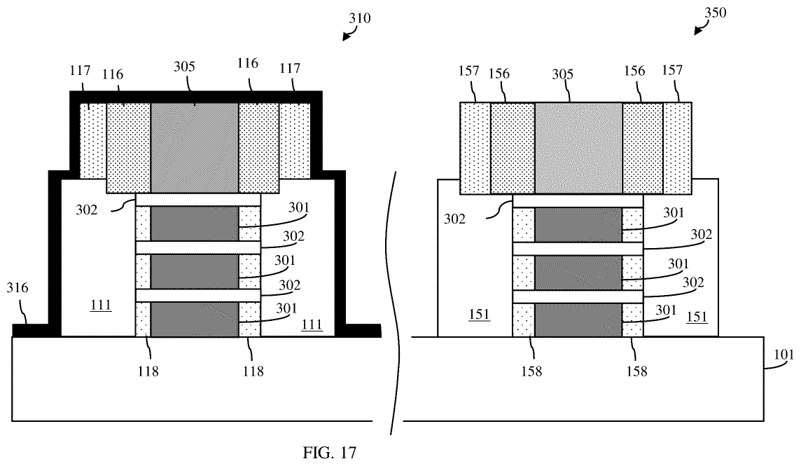

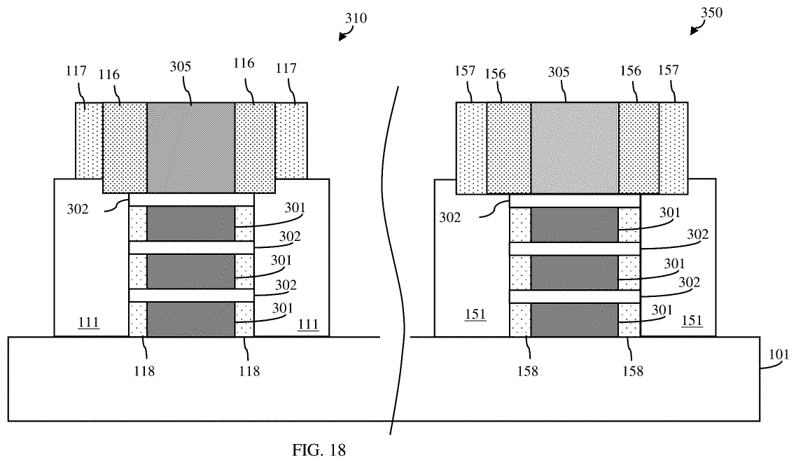

Source/drain regions 151 can subsequently be formed in source/drain recesses 351 (see process 236 and FIG. 17). Source/drain regions 151 can be formed, for example, by epitaxially growing a monocrystalline semiconductor material on the exposed vertical surfaces (i.e., end walls) of nanosheet semiconductor material 302 within source/drain recesses 351. This semiconductor material for source/drain regions can be, for example, monocrystalline silicon or some other suitable monocrystalline semiconductor material, which is preselected, for example, to improve channel mobility depending upon the conductivity type of GAAFET being formed. Additionally, source/drain regions 151 can be in situ doped, during epitaxial deposition, so as to have a suitable conductivity type and level given the conductivity type of the GAAFET being formed. For example, for an N-channel GAAFET, source/drain regions 151 can be in situ doped so as to have N-type conductivity at a relatively high conductivity level (i.e., N++ conductivity). As illustrated, the epitaxial deposition process can be performed so that source/drain regions 151 include: proximal portions 151p, which are adjacent to fin structure 320 and bound by both outer spacers 156 and additional outer spacers 157; and distal portions 151d, which extend laterally beyond additional outer spacers 157. Since proximal portions 151p of source/drain regions 151 for the second GAAFET are bound by both outer spacers 156 and additional outer spacers 157, they will be relatively long (as measured in a direction parallel to channel length) as compared to proximal portions 111p of source/drain regions 111 for the first GAAFET. Additionally, since distal portions 151d of source/drain regions 151 are not bound by outer spacers 156 and additional outer spacers 157, distal portions 151d can have greater cross-sectional areas than proximal portions 151p (i.e., distal portions 151d can have a greater height as measured from substrate 101 and a greater depth as measured parallel to the channel width than the proximal portions 151p). It should be noted that, as some point during processing, one or more anneal processes can be performed so as to drive some of the dopant material from source/drain regions 111 and source/drain regions 151 into the ends of the layers of nanosheet semiconductor material 302, thereby doping the source/drain extension regions.

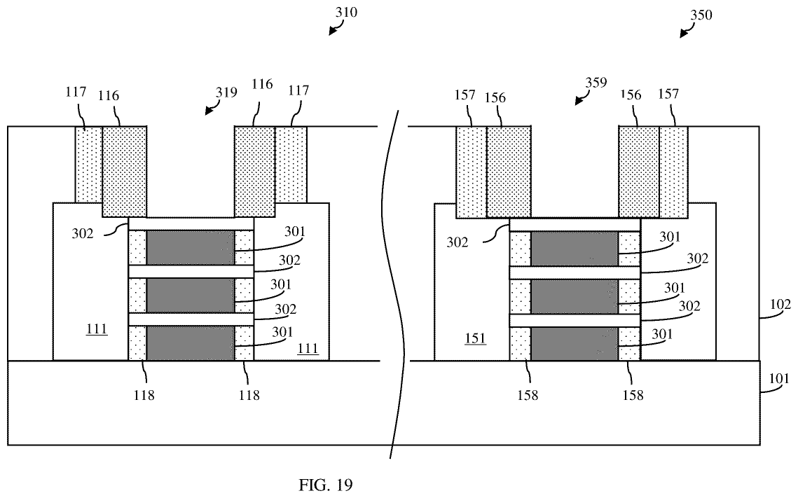

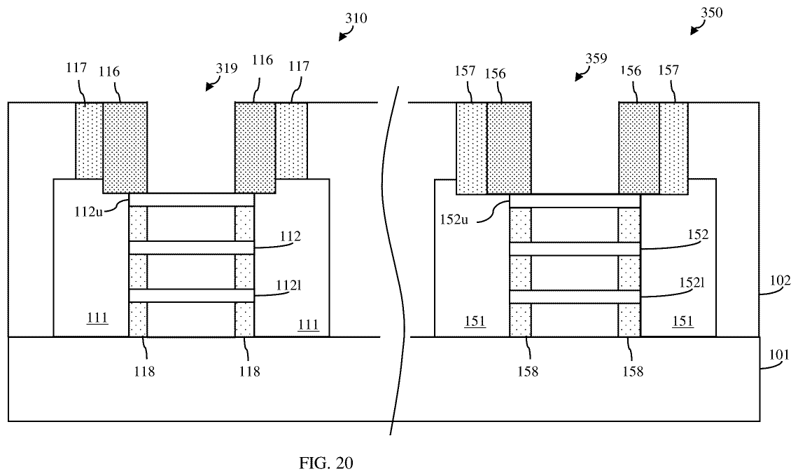

Hard mask layer 316 over first GAAFET region 310 can be selectively removed (see process 238). Then, conventional GAAFET processing can be performed in order to complete first and second GAAFETs 110, 150 (see process 240, FIG. 19, FIG. 20, and FIGS. 1A-1K). Process 240 can include, but is not limited to, the following.

A blanket layer of interlayer dielectric (ILD) material 102 (e.g., silicon dioxide (SiO₂) or any other suitable ILD material that is different from the dielectric materials of outer spacers 116, 156, and additional outer spacers 117, 157 can be deposited over the partially completed structure. ILD material 102 can then be polished (e.g., using a chemical mechanical polishing (CMP) process) to expose the sacrificial gates 305). Sacrificial gates 305 can then be selectively removed, thereby creating gate openings 319, 359 (see FIG. 19). That is, a selective etch process can be performed to selectively etch away the material of the sacrificial gates over the semiconductor materials of fin structure and also over the dielectric spacer materials and ILD, thereby creating gate openings. As mentioned above, formation of the sacrificial gates 305 typically includes deposition of a thin conformal dielectric layer (e.g., a thin conformal silicon dioxide layer) before depositing and patterning of the sacrificial gate material. This thin conformal dielectric layer will protect semiconductor materials during removal of the sacrificial gates 305. Following removal of sacrificial gates 305, the conformal dielectric layer can also be removed from the gate openings (e.g., by buffered hydrofluoric acid (BHF) in the case of a silicon dioxide layer).

Sacrificial semiconductor material 301 can be completely removed from between the layers of nanosheet semiconductor material 302 within the gate openings 319, 359 (see FIG. 20). For example, if nanosheet semiconductor material 302 is silicon (Si) and sacrificial semiconductor material 301 is silicon germanium (e.g., SiGe25%), then the sacrificial semiconductor material 301 can be selectively isotropically etched over nanosheet semiconductor material 302 and over the dielectric spacer materials using any of the following exemplary processes: a hydrogen chloride (HCl) or chlorine trifluoride (ClF₃) vapor phase etch process, a dry plasma etch process, or a wet etch process with process specifications designed to ensure the selective etch of silicon germanium over silicon and various dielectric materials. Alternatively, any other suitable selective isotropic etch process could be used.

The remaining layers of nanosheet semiconductor material 302 form distinct semiconductor nanosheets 112, 152. As illustrated, these semiconductor nanosheets 112, 152 have an essentially uniform thickness, extend laterally between source/drain regions 111, 151 and are stacked vertically. The lowermost semiconductor nanosheet 1121, 1521 is above, parallel to, and physically separated from substrate 101. One or more additional semiconductor nanosheets are stacked one above the other such that they are physically separated from and parallel to each other. Each nanosheet 112, 152 has end portions positioned laterally immediately adjacent to source/drain regions 111, 151 and a center portion positioned laterally between the end portions. Inner spacers 118, 158 are aligned below the end portions and physically separate source/drain regions 111, 151 from the gate opening. The center portions of the semiconductor nanosheets 112, 152 (including top, bottom and opposing side surfaces thereof) are exposed within the gate openings.

To achieve the structure shown in FIGS. 1A-1K, gates 113, 153 for the first and second GAAFETs 110, 150 can be formed in the gate opening wrapping around (i.e., adjacent to the top, bottom, and side surfaces) of the center portion of each semiconductor nanosheet 112, 152, as described in greater detail above with regard to the structure embodiments. Such gates 113, 153 can be formed, for example, using conventional replacement metal gate (RMG) formation techniques. That is, a gate dielectric layer 114, 154 (e.g., a high-K gate dielectric layer) can be conformally deposited so that the exposed surfaces of the semiconductor nanosheets within each gate opening are covered. Then, one or more gate conductor layers 115, 155 (e.g., one or more conformal work function metal layers, a fill metal layer, etc.) can be deposited on the gate dielectric layer. Various different RMG processing techniques are well known in the art and, thus, the details have been omitted from this specification in order to allow the reader to focus on the salient aspects of the disclosed method. However, it should be under gate 113, 153 can be formed concurrently so as to have essentially the same structure (e.g., same gate dielectric and conductor materials). Alternatively, gates 113 and 153 could be formed using discrete process steps so that the gate dielectric and/or gate conductor materials in gates 113 and 153 vary. For example, gates 113 and 153 could include different work function metals selected for optimal P-channel GAAFET and N-channel GAAFET performance, respectively. In any case, a dielectric gate cap (not shown) can also be formed on gates 113, 153. For example, conductive fill material within the gate openings can be recessed and a dielectric cap layer (e.g., a silicon nitride (SiN) cap layer) can be deposited over the partially completed structure. A polishing process (e.g., a CMP process) can be performed so as to remove any of the dielectric cap material from above the top surface of the ILD material 102, thereby forming the dielectric gate cap.

Additional processing can be performed in order to complete the semiconductor structure 100. This additional processing can include, but is not limited to, formation of metal plugs on the source/drain regions, formation of middle of the line (MOL) contacts, formation of back end of the line (BEOL) wiring, etc.

It should be understood that in the structures and method described above, a semiconductor material refers to a material whose conducting properties can be altered by doping with an impurity. Such semiconductor materials include, for example, silicon-based semiconductor materials (e.g., silicon, silicon germanium, silicon germanium carbide, silicon carbide, etc.) and III-V compound semiconductors (i.e., compounds obtained by combining group III elements, such as aluminum (Al), gallium (Ga), or indium (In), with group V elements, such as nitrogen (N), phosphorous (P), arsenic (As) or antimony (Sb)) (e.g., GaN, InP, GaAs, or GaP). A pure semiconductor material and, more particularly, a semiconductor material that is not doped with an impurity for the purposes of increasing conductivity (i.e., an undoped semiconductor material) is referred to in the art as an intrinsic semiconductor. A semiconductor material that is doped with an impurity for the purposes of increasing conductivity (i.e., a doped semiconductor material) is referred to in the art as an extrinsic semiconductor and will be more conductive than an intrinsic semiconductor made of the same base material. That is, extrinsic silicon will be more conductive than intrinsic silicon; extrinsic silicon germanium will be more conductive than intrinsic silicon germanium; and so on. Furthermore, it should be understood that different impurities (i.e., different dopants) can be used to achieve different conductivity types (e.g., P-type conductivity and N-type conductivity) and that the dopants may vary depending upon the different semiconductor materials used. For example, a silicon-based semiconductor material (e.g., silicon, silicon germanium, etc.) is typically doped with a Group III dopant, such as boron (B) or indium (In), to achieve P-type conductivity, whereas a silicon-based semiconductor material is typically doped with a Group V dopant, such as arsenic (As), phosphorous (P) or antimony (Sb), to achieve N-type conductivity. A gallium nitride (GaN)-based semiconductor material is typically doped with magnesium (Mg) to achieve P-type conductivity and with silicon (Si) or oxygen to achieve N-type conductivity. Those skilled in the art will also recognize that different conductivity levels will depend upon the relative concentration levels of the dopant(s) in a given semiconductor region. Furthermore, when a semiconductor region or layer is described as being at a higher conductivity level than another semiconductor region or layer, it is more conductive (less resistive) than the other semiconductor region or layer; whereas, when a semiconductor region or layer is described as being at a lower conductivity level than another semiconductor region or layer, it is less conductive (more resistive) than that other semiconductor region or layer.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should be understood that the terminology used herein is for the purpose of describing the disclosed structures and methods and is not intended to be limiting. For example, as used herein, the singular forms “a,” “an,” and “the” are intended to include the plural forms as well, unless the context clearly indicates otherwise. Additionally, as used herein, the terms “comprises,” “comprising,” “includes,” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a substrate; and
a transistor on the substrate, wherein the transistor includes:
semiconductor nanosheets extending laterally between source/drain regions, wherein the semiconductor nanosheets are stacked vertically, parallel, and physically separated and include at least a lowermost semiconductor nanosheet and an uppermost semiconductor nanosheet above the lowermost semiconductor nanosheet;
inner spacers below end portions of all of the semiconductor nanosheets; and
outer spacers above the end portions of the uppermost semiconductor nanosheet and further extending onto the source/drain regions, wherein the outer spacers are wider than the inner spacers.

2. The structure of claim 1,
wherein the transistor further includes a gate,
wherein the gate includes inner gate sections below center portions of the semiconductor nanosheets and an outer gate section at least above a center portion of the uppermost semiconductor nanosheet,
wherein the inner spacers are between the inner gate sections and the source/drain regions, and
wherein the outer spacers are positioned laterally adjacent to the outer gate section.

3. The structure of claim 2, wherein the outer gate section is further positioned laterally adjacent to opposing sides of the semiconductor nanosheets and the inner spacers.

4. The structure of claim 2,
wherein the source/drain regions include proximal portions positioned laterally immediately adjacent to the semiconductor nanosheets and isolated from the inner gate sections by the inner spacers,
wherein the source/drain regions further have distal portions,
wherein the proximal portions are between the semiconductor nanosheets and the distal portions, and
wherein heights of the distal portions are greater than heights of the proximal portions.

5. The structure of claim 4, wherein the transistor further includes additional outer spacers above the distal portions and positioned laterally immediately adjacent to the outer spacers.

6. The structure of claim 4, wherein the transistor further includes additional outer spacers above the proximal portions and positioned laterally between and immediately adjacent to the outer spacers and the distal portions.

7. The structure of claim 1, wherein end walls of the semiconductor nanosheets and the inner spacers are vertically aligned below the outer spacers.

8. A structure comprising:
a substrate; and
multiple transistors on the substrate, wherein each transistor of the multiple transistors includes:
semiconductor nanosheets extending laterally between source/drain regions, wherein the semiconductor nanosheets are stacked vertically, parallel, and physically separated and include at least a lowermost semiconductor nanosheet and an uppermost semiconductor nanosheet above the lowermost semiconductor nanosheet;
a gate, wherein the gate includes inner gate sections below center portions of the semiconductor nanosheets and an outer gate section above a center portion of the uppermost semiconductor nanosheet;
inner spacers below end portions of all of the semiconductor nanosheets between the inner gate sections and proximal portions of the source/drain regions; and
outer spacers positioned laterally adjacent to the outer gate section and further extending over the end portions of the uppermost semiconductor nanosheet onto the proximal portions of the source/drain regions, wherein the outer spacers are wider than the inner spacers.

9. The structure of claim 8,
wherein the source/drain regions further include distal portions,
wherein the proximal portions are between the semiconductor nanosheets and the distal portions and, and
wherein heights of the distal portions are greater than heights of the proximal portions.

10. The structure of claim 9, wherein depths of the distal portions are greater than depths of the proximal portions.

11. The structure of claim 9, wherein each transistor further includes additional outer spacers positioned laterally immediately adjacent to the outer spacers.

12. The structure of claim 11, wherein the multiple transistors include:
a first transistor, wherein, within the first transistor, the additional outer spacers are on the distal portions of the source/drain regions; and
a second transistor having a different type conductivity than the first transistor, wherein, within the second transistor, the additional outer spacers are above the proximal portions of the source/drain regions and positioned laterally between and immediately adjacent to the outer spacers and the distal portions.

13. The structure of claim 12, wherein the first transistor is a P-channel field effect transistor, and the second transistor is an N-channel field effect transistor.

14. The structure of claim 12, wherein the first transistor is an N-channel field effect transistor, and the second transistor is a P-channel field effect transistor.

15. The structure of claim 8, wherein, within each transistor, end walls of the semiconductor nanosheets and the inner spacers are vertically aligned below the outer spacers.

16. The structure of claim 8, wherein, within each transistor, the outer gate section is further positioned laterally adjacent to opposing sides of the semiconductor nanosheets and the inner spacers.

17. A method comprising:
providing a substrate; and
forming a transistor on the substrate, wherein the transistor includes:
semiconductor nanosheets extending laterally between source/drain regions, wherein the semiconductor nanosheets are stacked vertically, parallel, and physically separated and include at least a lowermost semiconductor nanosheet and an uppermost semiconductor nanosheet above the lowermost semiconductor nanosheet;
inner spacers below end portions of all of the semiconductor nanosheets; and
outer spacers above the end portions of the uppermost semiconductor nanosheet and further extending onto the source/drain regions, wherein the outer spacers are wider than the inner spacers.

18. The method of claim 17,
wherein the substrate is a first semiconductor material,
wherein the forming of the transistor includes:
forming a stack of alternating layers of a second semiconductor material and the first semiconductor material;
patterning the stack into a multi-layered fin structure;
forming a sacrificial gate adjacent to top and opposing side surfaces of the multi-layered fin structure;
forming the outer spacers adjacent to sidewalls of the sacrificial gate;
forming source/drain recesses in multi-layered fin structure;
selectively etching back exposed vertical surfaces of the first semiconductor material and the second semiconductor material with the first semiconductor material being etched back a greater distance to form inner spacer openings;
forming inner spacers in the inner spacer openings; and
forming source/drain regions in the source/drain recesses, wherein the source/drain regions include distal portions and proximal portions extending laterally between the semiconductor nanosheets and the distal portions, and wherein heights of the distal portions are greater than heights of the proximal portions.

19. The method of claim 18, wherein the forming of the transistor further includes, after the forming of the source/drain regions, forming additional outer spacers on the distal portions and positioned laterally immediately adjacent to the outer spacers.

20. The method of claim 18, wherein the forming of the transistor further includes, before the forming of the source/drain recesses, forming additional outer spacers on the proximal portions positioned laterally immediately adjacent to the outer spacers.
